(19) United States
(12) Patent Application Publication
(10) Pub. No.: US 2005/0230597 A1
(43) Pub. Date: Oct. 20, 2005

(54) IMAGE SENSING DEVICE FOR IMPROVING IMAGE QUALITY AND REDUCING COLOR SHIFT EFFECT

(76) Inventors: Chih-Cheng Hsieh, Hsin-Chu City (TW); Chien-Chang Huang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/904,742

(22) Filed: Nov. 24, 2004

(30) Foreign Application Priority Data
Apr. 15, 2004 (TW) 093110511

(51) Int. Cl. G01J 3/50; H01L 27/00; H01J 5/16; H01J 40/14; G01V 8/00; G01N 21/86

(52) U.S. Cl. 250/208.1; 250/226

(57) ABSTRACT

An image sensing device includes a plurality of color units. Each color unit has a photosensor element for converting light of a specific spectrum range into an electrical signal. Different arrangements of the photosensor elements are set in diagonal directions. In this way, such layout is capable of reducing color shift effect.

### BACKGROUND OF INVENTION

1. Field of the Invention

The invention relates to an image sensor, and more particularly, to an image sensor utilizing mirror-symmetrical layout to reduce color shift effect.

2. Description of the Prior Art

As with rapid development of digital image devices, digital image devices have become more popular than traditional analog image devices. However, in order to obtain better quality of digital images with higher resolution, improvement of the image sensor which is used for photoelectric conversion is necessary. However, in recent years, a solid-state image sensor has been miniaturized, with which a photosensor element is reduced and a drop of the sensitivity is caused.

Please refer to FIG. 1 showing a schematic diagram of a conventional digital image-capturing device 10. The digital image-capturing device 10 comprises a lens 12 and an image sensor 20. The image sensor 20 comprises a plurality of sensing units 30 each comprising a microlens 24, a color filter 25 and a photosensor element 22. When light enters into the image-capturing device 10, the light will pass through the lens 12 and project onto the plurality of sensing units 30 through the lens 12. Each microlens 24 will collect the incident light onto the photosensor element 22 of the sensing unit 30, after filtering out light with different spectrums by using the color filter 25. For example, the blue color filter 25b is used for filtering out the light inconsistent with the blue light spectrum, and the green light filter 25g is used for filtering out the light inconsistent with the green light spectrum. Finally, the photosensor element 22 transforms the filtered light into an electrical signal. Generally speaking, the plurality of sensing units 30 are arranged in a regular manner called a Bayer pattern color filter array, as shown in FIG. 2. In FIG. 2, G, B, R respectively indicates sensing units 30 for sensing green light, blue light, and red light. An area formed by two green sensing units 30, a blue sensing unit 30 and a red sensing unit 30 serves as a pixel 11. This is because human eyes have more sensitivity for green light than red and blue light, such that a 2:1:1 arrangement of green, blue, red sensing units is used to be consistent with real image color. Each sensing unit 30 has a photosensor element 22 formed on a silicon substrate 16. A transfer electrode 14 formed on the photosensor element 22 is used for transferring the generated electrical signals.

Please refer to FIG. 1 and FIG. 3. FIG. 3 shows a simplified layout of conventional image sensors 20. Each sensing unit 30r, 30g, 30b contains an amplifier 32 coupled to the transfer electrode 14 for transmitting the sensed electrical signal to row data lines or column data lines. The image capturing device 10 reconstructs the pixels 11 to form an image based on the electrical signals from the row data line and the column data line. In addition, a fill factor is defined as a ratio of a pixel area (d*d) to that of a photosensor element 22 of a pixel. The fill factor is indicated as follows:

$$ff = \frac{Av}{A} \times 100 \%$$

where ff indicates a fill factor, A indicates an area of a color unit, and Av indicates an area of the photosensor element 22 within a color unit.

The higher the image resolution is required, the smaller each pixel area is, and the smaller the area of the sensing unit 30 is. Although the larger area of the photosensor element (i.e. larger value of the fill factor) is, the better the photosensor effect obtained is, it is more and more difficult to manufacture a small area of the amplifier 32.

As shown in FIG. 3, the conventional sensing unit has regular arrangement. Such layout results in uneven sensing effect, and such phenomenon is more obvious at a bottom-right side of FIG. 3. Please refer to FIG. 1 and FIG. 4. FIG. 4 shows a simplified layout of the sensing units depicted in FIG. 3. For clarity, FIG. 4 amplifiers and other connections therewith are omitted in FIG. 4 and the oblique-line area indicates light-focused area via the microlens. In FIG. 1, a light A entering the sensing unit 30 located at the center of the image sensor 20 can be completely sensed by the photosensor element 22, but a light B entering the sensing unit 30 located at a corner of the image sensor 20 has a deviation so that the light B fails to exactly project onto the photosensor element 22. Take FIG. 4 for example, light A is projected onto the area 211 of the photosensor element 201g, but the light B is projected onto a deviation area 212 of the photosensor element 202g. Similarly, light is probably projected on the deviation areas 213, 214, 215 of the photosensor element 203g, 204g, 205g, because light via microlens will deviate. In other words, a light A entering the sensing unit 30 located at the center of the image sensor 20 can be completely sensed by the photosensor element 22, but a light B entering the sensing unit 30 located at a corner of the image sensor 20 has a deviation so that the light B fails to exactly project onto the photosensor element 22. Therefore, an error occurs due to inconsistent ratio of received light for a pixel at the corner, thereby causing a color shift effect and deterioration of sensing quality. The photosensor element 22 of the sensing unit 30 at the corner will receive less light due to a larger incident angle. Uneven light sensing of the image sensor 20 results in an inconsistent image quality, which is a problem that needs to be solved.

### SUMMARY OF INVENTION

According to the claimed invention, an image sensing device for reducing color shift effect comprises a plurality of color units each comprising a photosensor element for converting light of a specific spectrum range into an electrical signal. Different arrangements of the photosensor elements are set in diagonal directions.

These and other objectives of the claimed invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 shows a schematic diagram of a digital image-capturing device according to the prior art.

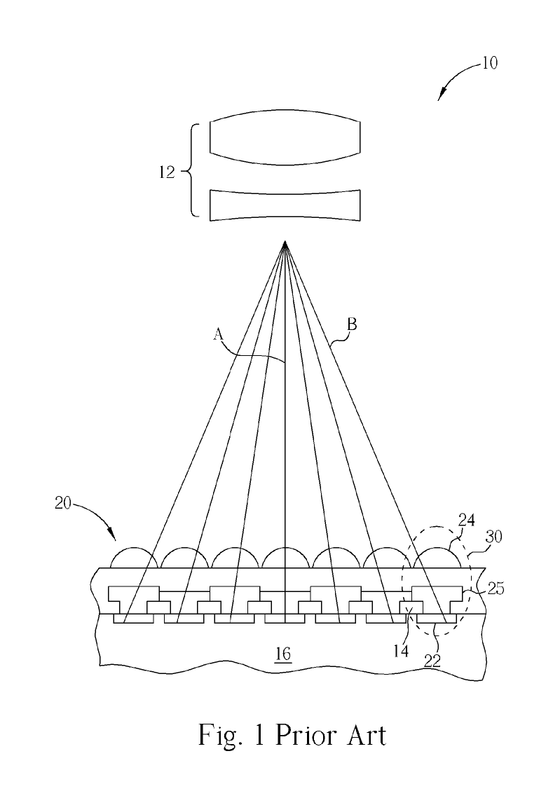

FIG. 2 is a schematic diagram of a Bayer pattern color filter array.

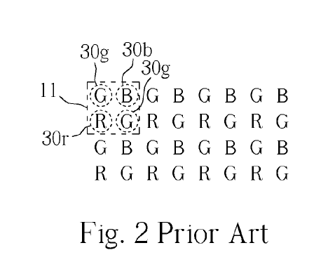

FIG. 3 shows a simplified layout of conventional image sensor.

FIG. 4 shows a simplified layout of the sensing units depicted in FIG. 3.

FIG. 5 shows a layout of a first embodiment of an image sensor according to the present invention.

FIG. 6 shows a schematic diagram of the image sensor depicted in FIG. 5.

FIG. 7 shows a layout of a second embodiment of an image sensor according to the present invention.

FIG. 8 shows a layout of a third embodiment of an image sensor according to the present invention.

FIG. 9 shows a layout of a fourth embodiment of an image sensor according to the present invention

### DETAILED DESCRIPTION

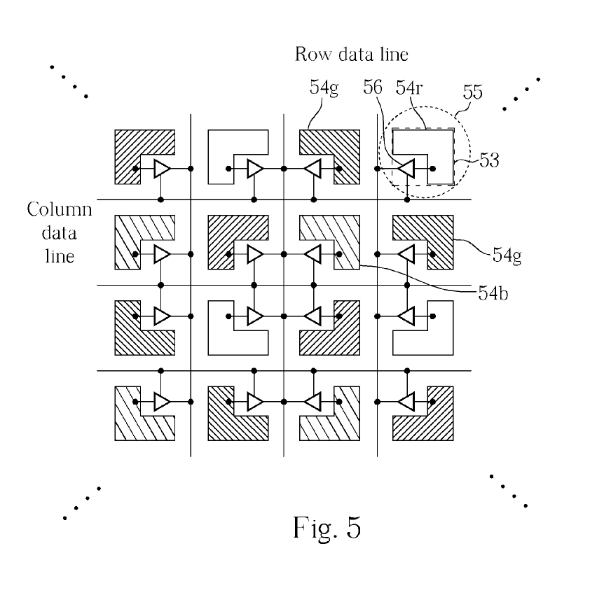

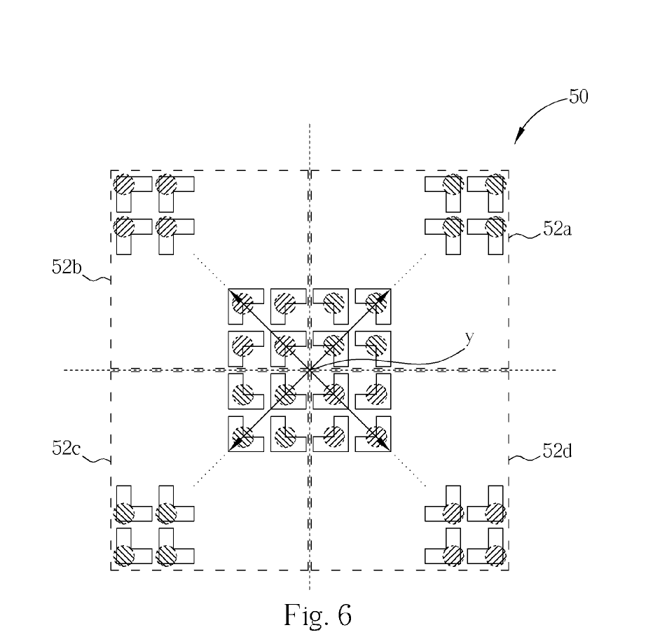

Please refer to FIG. 5 and FIG. 6. FIG. 5 shows a layout of a first embodiment of the image sensor according to the present invention. FIG. 6 shows a schematic diagram of the image sensor 50 depicted in FIG. 5. The image sensor 50 comprises a plurality of color units 55, each having an amplifier 56 and a photosensor element 54. Each color unit 55 further comprises a filter element 53 formed over the photosensor element 54 for filtering out light in accordance with a specific spectrum (for simplicity, only a color unit 55 and a filter element 53 are labeled in FIG. 5, and the filter element 53 is actually formed over the amplifier 56 and the photosensor element 54). The photosensor element 54 is used for transforming the filtered light into electrical signals. As can be seen in FIG. 5, the photosensor elements 54r, 54g, 54b are respectively used for receiving red, green, blue light through the filter element 53 and for transforming these lights into electrical signals. The amplifier 56 coupled to the photosensor element 54 is used for amplifying the transformed electrical signals and transmitting them to row data line or column data line. Finally, the processor (not shown) may reconstruct an image based on the magnitude of electrical signals transmitted via the row data line and column data line.

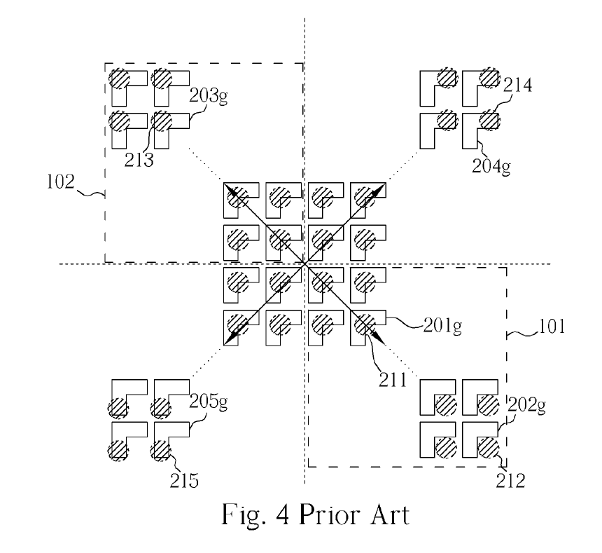

As shown in FIG. 6, amplifiers 56 are omitted in FIG. 6 and the oblique-line area stands for the light-focused area via the microlens. The image sensor 60 has four areas 52a-52d, in each of which the arrangements of the photosensor elements 54 are identical. The arrangements of the photosensor elements 54 in adjacent areas are separated by a 90-degree angle, and those of the photosensor elements 54 in diagonal areas are separated by a 180-degree angle. Compared with a layout in FIG. 4, in which the areas 101 and 102 sensed non-symmetrical amounts, in the layout of FIG. 6, the light-focused areas of the photosensor element 54 at the four areas 52a-52d are more even, so that a better sensing effect is obtained.

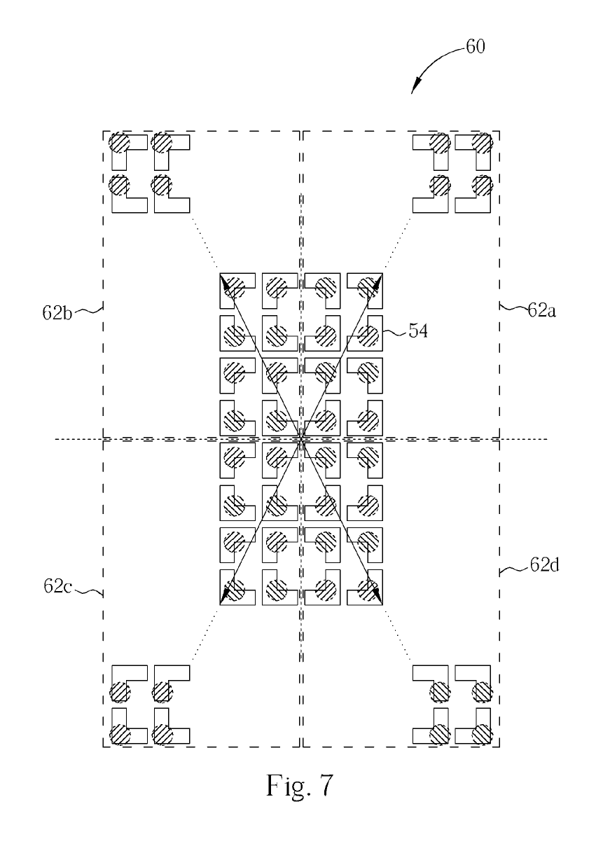

Please refer to FIG. 7, which shows a layout of a second embodiment of an image sensor 60 according to the present invention. For clarity, amplifiers 56 are omitted in FIG. 7 and the oblique-line area stands for the light-focused area via the microlens. The image sensor 60 has four areas 62a-62d, in each of which the arrangements of the photosensor elements 54 are identical. The two adjacent and different arrangement photosensor elements can share a single amplifier. Compared to the layout in FIG. 4, the light-focused areas of the photosensor element 54 at the four corners are more even, so that a better sensing effect is obtained.

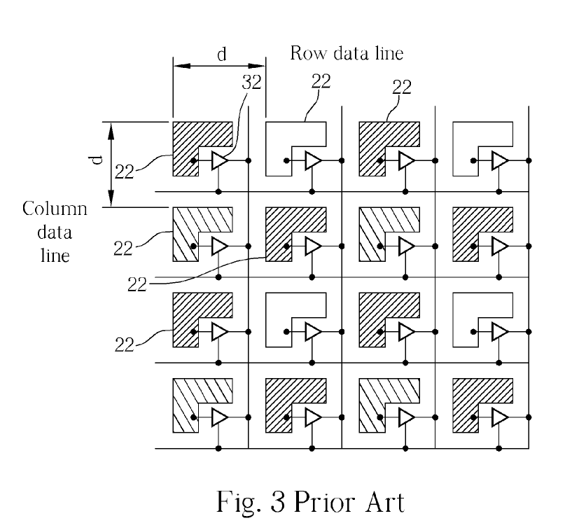

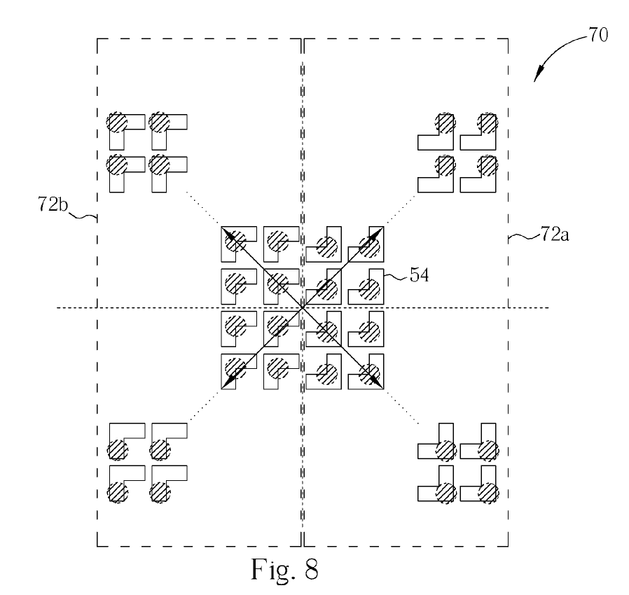

Please refer to FIG. 8, which shows a layout of a third embodiment of an image sensor 70 according to the present invention. For clarity, the amplifiers 56 are omitted in FIG. 8 and the oblique-line area stands for the light-focused area via the microlens. The image sensor 70 has two areas 72a, 72b, in which the arrangements of the photosensor elements 54 are identical. And the arrangements of the photosensor elements 54 respectively located in adjacent areas are separated by a 180-degree angle. Compared to the layout in FIG. 3, the light-focused area of the photosensor element 54 at the corner of the two areas 72a, 72b is more even, so that a better sensing effect is obtained.

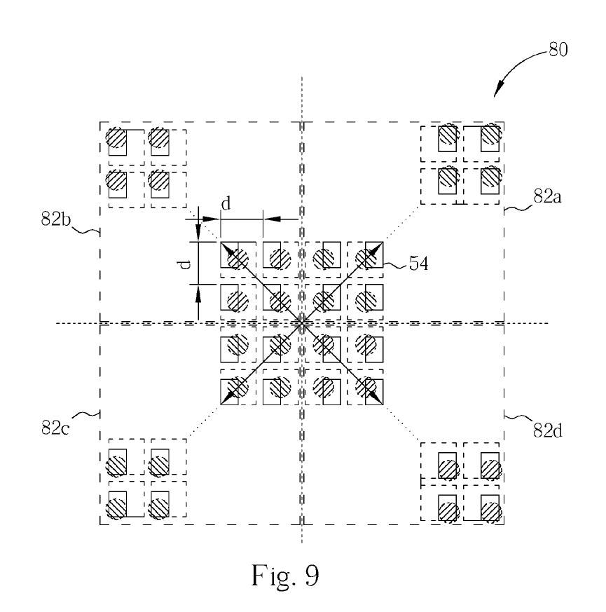

Please refer to FIG. 9, which shows a layout of a fourth embodiment of an image sensor 80 according to the present invention. For clarity, amplifiers 56 are omitted in FIG. 9 and the oblique-line area stands for the light-focused area via the microlens. The image sensor 80 has four areas 82a-82d, in each of which the arrangements of the photosensor elements 54 are identical. In addition, different from the L-shape photosensor element 54, the photosensor element 54 as shown in FIG. 9 has a rectangular shape. The arrangements of the photosensor elements 54 located in adjacent area are mirror-symmetrical. Compared to the layout in FIG. 4, the light-focused area of the photosensor element 54 at the four corners is more even, so that a better sensing effect is obtained.

Notice that the plurality of color units 55 illustrated in FIGS. 6-9 are aligned as a Bayer pattern color filter array. The filter elements are used for filtering out red, green, blue color light or yellow, magenta, cyan color light. The photosensor element can be a charge-coupled device or a CMOS photosensor. In addition, a L-shape of the photosensor element 54 illustrated in FIGS. 6-8 can be replaced by a rectangle-shape, triangle-shape, or pentagon-shape, etc.

In addition, the adjacent photosensor elements of which the arrangements are different and coupled to an identical row data line and column data line are capable of being coupled to a single amplifier, thereby saving layout area.

To sum up, the layout of the photosensor elements are concluded as follows:
(a) The arrangements of photosensor elements of color units in diagonal positions are different. Furthermore, no matter what the shape of the photosensor is, the arrangements of photosensor elements of color units in diagonal positions are mirror-symmetrical.
(b) Aside from boundary conditions, the arrangement of each photosensor element in each area is identical.

Certainly, the photosensor elements of the color unit located at the four corners and in diagonal positions are mirror-symmetrical, but the arrangement of the photosensor element located in the middle remains. In other words, the arrangements of the photosensor elements in each area are not necessary identical.

In contrast to the prior art, the present invention image sensor utilizes mirror-symmetrical arrangements of photosensor elements of the color units in diagonal positions. Therefore, for a pixel at a corner, its green photosensor element, blue photosensor element and red photosensor element cause a consistent amount of sensitivity. Furthermore, the adjacent photosensor elements of which the arrangements are different and coupled to an identical row data line and column data line are capable of being coupled to a single amplifier, thereby saving a layout area of an image sensor.

Those skilled in the art will readily observe that numerous modifications and alterations of the device may be made while retaining the teachings of the invention. Accordingly, the above disclosure should be construed as limited only by the metes and bounds of the appended claims.

1. An image sensing device for reducing color shift effect comprising:
a plurality of color units each comprising a photosensor element for converting light of a specific spectrum range into an electrical signal; wherein different arrangements of the photosensor elements are set in diagonal directions.

2. The image sensing device of claim 1, wherein the arrangements of the photosensor elements of the colors unit at opposed diagonals are separated by a 180-degree angle.

3. The image sensing device of claim 1, wherein the plurality of color units are set in a plurality of areas, and the arrangement of all photosensor elements of the color units in the same area is identical.

4. The image sensing device of claim 3 comprising four areas, wherein the arrangements of the photosensor elements of the color units respectively in adjacent areas are separated by a 90 degree angle.

5. The image sensing device of claim 3 comprising four areas, wherein the arrangements of the photosensor elements of the color units respectively in different areas are separated by a 180-degree angle.

6. The image sensing device of claim 1, wherein each color unit comprises an amplifier, coupled to the photosensor element, for amplifying the electrical signal generated by the photosensor element.

7. The image sensing device of claim 1, wherein two adjacent photosensor elements with different arrangements are coupled to a single amplifier.

8. The image sensing device of claim 1, wherein each photosensor element is a charge-coupled device (CCD).

9. The image sensing device of claim 1, wherein each photosensor element is a CMOS photosensor.

10. The image sensing device of claim 1, wherein the plurality of color units are aligned as a Bayer pattern color filter array.

11. The image sensing device of claim 1, wherein each color unit further comprises a filter element for filtering out light inconsistent with the red, green, or blue light spectrum.

12. The image sensing device of claim 1, wherein each color unit further comprises a filter element for filtering out light inconsistent with the yellow, magenta, or cyan light spectrum.
